(19) United States
(12) Patent Application Publication
(10) Pub. No.: US 2026/0148784 A1
(43) Pub. Date: May 28, 2026

(54) ELECTRONIC FUSE MEMORY

(71) Applicant: Shanghai Huali Integrated Circuit Corporation, Shanghai (CN)

(72) Inventor: Ying YAN, Shanghai (CN)

(73) Assignee: Shanghai Huali Integrated Circuit Corporation, Shanghai (CN)

(21) Appl. No.: 19/308,277

(22) Filed: Aug. 24, 2025

(30) Foreign Application Priority Data
Nov. 22, 2024 (CN) 202411686952.3

(51) Int. Cl. G11C 17/16

(52) U.S. Cl. CPC G11C 17/16

(57) ABSTRACT

The present disclosure discloses an electronic fuse memory, which is added with an address switching module and an output mode selection module on the basis of conventional basic function modules, and is added with a dual-bit redundant mode enable signal DB as an enable signal for the dual-bit redundant working mode on the basis of original control signals, thus providing two working modes, i.e., a normal working mode and a dual-bit redundant working mode, for customers to select. In the normal working mode, all storage space can be used, and in the dual-bit redundant working mode, a redundant backup function can be achieved, thus achieving selectable input address length and selectable output result, ensuring the implementation of conventional and redundant operations. In the same electronic fuse memory, the capacity and the reliability can be balanced.

### CROSS-REFERENCE TO RELATED APPLICATIONS

This application claims priority to Chinese patent application No. 202411686952.3, filed on Nov. 22, 2024, the disclosure of which is incorporated herein by reference in its entirety.

### TECHNICAL FIELD

The present disclosure belongs to the technical field of integrated circuit design, and in particular to an electronic fuse (efuse) memory.

### BACKGROUND

An electronic fuse (efuse) memory is a One-Time Programmable (OTP) memory, which implements a programming function by fusing a fuse based on an Electronic Migration (EM) principle. A reading module inside the electronic fuse (efuse) memory is responsible for converting a fuse resistance value into a corresponding logic value. Its working principle involves comparing the fuse resistance before and after fusing with a reference resistance through a comparison circuit and generating different voltage levels for output.

Due to special or accidental reasons, the electronic fuse (efuse) memory may experience phenomena such as incomplete fuse fusing during programming or insufficient resistance after programming, causing the reading module to output an incorrect logic value when comparing the reference resistance with the programmed resistance

To enhance system reliability, the electronic fuse (efuse) memory operates in a dual-bit redundant backup mode. Its working principle is as shown in FIG. 1. Two independent fuse memory cells operate under completely identical address control signals. A logic OR operation is performed on output results of the two independent fuse memory cells during a reading operation to form a final output Dout, that is, the same content programming is performed on the two fuse memory cells at the same time. If a problem occurs in the programming of one, the other fuse memory cell that is programmed normally may serve as a backup, so as to reduce the probability of failure. After the logic OR operation is performed on the output results of the two independent fuse memory cells during the reading operation, a correct logic value output Dout is obtained. This mode requires two addresses to store the same data, the probability that the two independent fuse memory cells fail to program at the same time is lower, and the programming reliability is very high, but its actual storage address is only half of the entire memory capacity address. The actual storage area of the memory is doubled, and it is not flexible to use. Under working conditions with very high programming reliability, this working mode uses two addresses to store the same data, and the actual storage area is doubled, but it is not flexible to use. Even under working conditions with very high programming reliability (that is, there is no need to backup), customers must give up half of the storage space when using electronic fuse (efuse) memories, and equivalently the electronic fuse (efuse) memories lose half of the chip area.

### BRIEF SUMMARY

An electronic fuse memory provided in the present disclosure includes a basic function module 10, an address switching module 11, and k output mode selection modules 12, where
the basic function module 10 has n+1 function address input ends AP<n:0> and 2 k fuse memory cell output ends; (m+1)th to nth function address input ends AP<n:m+1> are used as function bit address input ends, and 0th to mth function address input ends AP<m:0> are used as function word address input ends, where M is a positive integer, n is an integer greater than m, and k=2^{n-m};
the basic function module 10 includes k memory cell pairs, and each memory cell pair includes two fuse memory cells; outputs of two fuse memory cells of an ith memory cell pair are respectively SA<2i> and SA<2i−1>, where i is a positive integer less than or equal to k;
the address switching module 11 outputs n+1 bits of switching address input signals A<n:0> to the corresponding function address input ends of the basic function module 10 under the control of a dual-bit redundant mode enable signal DB;
the k output mode selection modules 12, under the control of the dual-bit redundant mode enable signal DB and a multiplexing selection signal MUX2, read out data stored in a normal working mode or data stored in a dual-bit redundant working mode of the basic function module 10;
control ends of all output mode selection modules 12 are respectively connected to the dual-bit redundant mode enable signal DB and the multiplexing selection signal MUX2;
two input ends of an ith output mode selection module 12 are respectively connected to the outputs SA<2i> and SA<2i−1> of the two fuse memory cells of the ith memory cell pair;
during a reading operation,
in a case that the dual-bit redundant mode enable signal DB is 0, 0th-bit to nth-bit switching address input signals A<n:0> in total of n+1 bits are all valid, and the address switching module 11 is in the normal working mode, the 0th-bit to mth-bit switching address input signals A<m:0> are outputted as word addresses to m+1 function word line address input ends AP<m:0> of the basic function module 10, and the (m+1)th-bit to nth-bit switching address input signals A<n:m+1> are correspondingly outputted as bit addresses to n−m function bit line address input ends AP<n:m+1> of the basic function module 10;
in a case that the dual-bit redundant mode enable signal DB is 1, the 0th-bit to (n−1)th-bit switching address input signals A<n−1:0> are valid, the nth-bit switching address input signal A<n> is invalid, the address switching module 11 is in the dual-bit redundant working mode, the 0th-bit to (m−1)th-bit switching address input signals A<m−1:0> are outputted as word addresses to m function word line address input ends AP<m−1:0> of the basic function module 10, the mth-bit to (n-1)th-bit switching address input signals A<n−1:m> are outputted as bit addresses to the other n−m function bit line address input ends AP<n:m+1> of the basic function module 10, and the mth-bit switching address input signal A<m> is simultaneously outputted as the multiplexing selection signal MUX2 to the k output mode selection modules 12;
in a case that the dual-bit redundant mode enable signal DB is 0, the k output mode selection modules 12 are in the normal working mode; in a case that the multiplexing selection signal MUX2 is 1, an output of the ith output mode selection module 12 is SA<2i>; in a case that the multiplexing selection signal MUX2 is 0, the output of the ith output mode selection module 12 is SA<2i−1>;
in a case that the dual-bit redundant mode enable signal DB is 1, the k output mode selection modules 12 are in the dual-bit redundant working mode, and the output of the ith output mode selection module 12 is to perform a logic OR operation on the outputs SA<2i−1> and SA<2i> of the two fuse memory cells of the ith memory cell pair.

In some embodiments, during a programming operation,
in a case that the dual-bit redundant mode enable signal DB is 0, the 0th-bit to nth-bit switching address input signals A<n:0> in total of n+1 bits are all valid, and the address switching module 11 is in the normal working mode and independently writes corresponding data respectively to the 2 k fuse memory cells of the basic function module 10;
in a case that the dual-bit redundant mode enable signal DB is 1, the 0th-bit to (n−1)th-bit switching address input signals A<n−1:0> are valid, the nth-bit switching address input signal A<n> is invalid, the address switching module 11 is in the dual-bit redundant working mode and writes data respectively to the k memory cell pairs of the basic function module 10, and the same data are written to the two fuse memory cells of the same one of the k memory cell pairs.

In some embodiments, the address switching module 11 includes main transmission gates TGB and auxiliary transmission gates TGA;
the mth-bit switching address input signal A<m> is connected to an input end of an mth auxiliary transmission gate TGA<m>;
an output end of the mth auxiliary transmission gate TGA<m> is connected to an (m+1)th function address input end AP<m+1> of the basic function module 10;
an input end of a jth auxiliary transmission gate TGA<j> is connected to a jth-bit switching address input signal A<j>, and an output end of the jth auxiliary transmission gate TGA<j> is connected to a (j+1)th function address input end AP<j+1> of the basic function module 10, where j is an integer greater than or equal to m and less than n;
an input end of a jth main transmission gate TGB<j> is connected to the jth-bit switching address input signal A<j>, and an output end of the jth main transmission gate TGB<j> is connected to a jth function address input end AP<j> of the basic function module 10;
an input end of an nth main transmission gate TGB<n> is connected to the nth-bit switching address input signal A<n>, and an output end of the nth main transmission gate TGB<n> is connected to an nth function address input end AP<n> of the basic function module 10;
the main transmission gates TGB are turned on in a case that DB is 0 and turned off in a case that DB is 1;
the auxiliary transmission gates TGA are turned on in a case that DB is 1 and turned off in a case that DB is 0.

In some embodiments, each of the main transmission gates TGB and the auxiliary transmission gates TGA is composed of an NMOS transistor and a PMOS transistor;
a drain end of the NMOS transistor is short-circuited to a source end of the PMOS transistor as an input end of each transmission gate;
a source end of the NMOS transistor is short-circuited to a drain end of the PMOS transistor as an output end of each transmission gate;
a gate of the PMOS transistor of each main transmission gate TGB is connected to DBA, and a gate of the NMOS transistor is connected to DBB;
a gate of the PMOS transistor of each auxiliary transmission gate TGB is connected to DBB, and a gate of the NMOS transistor is connected to DBA;
DBA and the dual-bit redundant mode enable signal DB are out of phase, and DBB and the dual-bit redundant mode enable signal DB are in phase;
a state of the dual-bit redundant mode enable signal DB at a high level is state 1, and a state at a low level is state 0.

In some embodiments, the address switching module 11 further includes word line transmission gates TGW;
the 0th-bit switching address input signal A<0> to the mth-bit switching address input signal A<m> are respectively connected to input ends of a 0th word line transmission gate TGW<0> to an mth word line transmission gate TGW<m>;

output ends of the 0th word line transmission gate TGW<0> to the mth word line transmission gate TGW<m> are respectively connected to the 0th to mth function address input ends AP<m:0> of the basic function module 10;

each word line transmission gate TGW<m:0> is turned on in a case that the electronic fuse memory is powered on.

In some embodiments, each word line transmission gate TGW<m:0> is composed of an NMOS transistor and a PMOS transistor;
a drain end of the NMOS transistor is short-circuited to a source end of the PMOS transistor as an input end of each word line transmission gate;
a source end of the NMOS transistor is short-circuited to a drain end of the PMOS transistor as an output end of each word line transmission gate;
a gate of the PMOS transistor of each word line transmission gate TGW is connected to a low working voltage VSS, and a gate of the NMOS transistor is connected to a high working voltage VDD.

In some embodiments, each output mode selection module 12 includes an even transmission gate TGo, an odd transmission gate TGe, a normal transmission gate TGn, a redundant transmission gate TGr, a NOR gate, and a NOT gate INV;
two input ends of the NOR gate of the ith output mode selection module 12 are respectively connected to the outputs SA<2i> and SA<2i−1> of the two fuse memory cells of the ith memory cell pair of the basic function module 10; an output end of the NOR gate is connected to an input end of the NOT gate INV; an output end of the NOT gate INV is connected to an input end of the redundant transmission gate TGr; an output end of the redundant transmission gate TGr is connected to an ith selection output end DO<i>; an input end of the even transmission gate TGo is connected to the output SA<2i> of one fuse memory cell of the ith memory cell pair of the basic function module 10, and an output end is short-circuited to an input end of the normal transmission gate TGn; an input end of the odd transmission gate TGe is connected to the output SA<2i−1> of the other fuse memory cell of the ith memory cell pair of the basic function module 10, and an output end is short-circuited to the input end of the normal transmission gate TGn; an output end of the normal transmission gate TGn is connected to the ith selection output end DO<i>;
the normal transmission gate TGn is turned on in a case that DB is 0 and turned off in a case that DB is 1;
the redundant transmission gate TGr is turned on in a case that DB is 1 and turned off in a case that DB is 0;
the even transmission gate TGo is turned on in a case that the multiplexing selection signal MUX2 is 1 and turned off in a case that the multiplexing selection signal MUX2 is 0;

The odd transmission gate TGe is turned on in a case that the multiplexing selection signal MUX2 is 0 and turned off in a case that the multiplexing selection signal MUX2 is 1.

In some embodiments, each of the even transmission gate TGo, the odd transmission gate TGe, the normal transmission gate TGn, and the redundant transmission gate TGr is composed of an NMOS transistor and a PMOS transistor;
a drain end of the NMOS transistor is short-circuited to a source end of the PMOS transistor as an input end of each transmission gate;
a source end of the NMOS transistor is short-circuited to a drain end of the PMOS transistor as an output end of each transmission gate;
a gate of the PMOS transistor of the redundant transmission gate TGr is connected to DBA, and a gate of the NMOS transistor is connected to DBB;
a gate of the PMOS transistor of the normal transmission gate TGn is connected to DBB, and a gate of the NMOS transistor is connected to DBA;
a gate of the PMOS transistor of the even transmission gate TGo is connected to PSB, and a gate of the NMOS transistor is connected to PSA;
a gate of the PMOS transistor of the odd transmission gate TGe is connected to PSA, and a gate of the NMOS transistor is connected to PSB;
DBA and the dual-bit redundant mode enable signal DB are out of phase, and DBB and the dual-bit redundant mode enable signal DB are in phase;
PSB and the mth-bit switching address input signal A<m> are out of phase, and PSA and the mth-bit switching address input signal A<m> are in phase;
a state of the dual-bit redundant mode enable signal DB at a high level is state 1, and a state at a low level is state 0.

In some embodiments, n=12, m=7, and k=32.

In the electronic fuse memory provided in the present disclosure, an address switching module 11 and output mode selection modules 12 are added on the basis of the conventional basic function module 10, a dual-bit redundant mode enable signal DB is added as an enable signal for the dual-bit redundant working mode on the basis of the original control signal and is used for controlling the state of the address switching module 11, and the settings of the dual-bit redundant mode enable signal DB and the switching address input signal are different in the normal working mode and the dual-bit redundant working mode; in a case that DB=0, addresses A<n:0> are valid, and the address switching module 11 is in the normal working mode; in a case that DB=1, addresses A<n−1:0> are valid, and the address switching module 11 is in the dual-bit redundant working mode; during the reading operation, the output mode selection module 12 have the function of switching between the normal output and the dual-bit redundant output; under the control of the dual-bit redundant mode enable signal DB and the multiplexing selection signal MUX2, the k output mode selection modules 12 not only can read the data stored in the normal working mode of the 2 k fuse memory cells of the basic function module 10, but also can read the data stored in the dual-bit redundant working mode of the k memory cell pairs of the basic function module 10; the output mode selection modules 12 not only can achieve the separate output of the data stored in each fuse memory cell, but also can perform a logic OR operation on the two fuse memory cells of the same memory cell pair before output. The electronic fuse memory can provide two working modes, i.e., a normal working mode and a dual-bit redundant working mode, for customers to select. In the normal working mode, all storage space can be used, and in the dual-bit redundant working mode, a redundant backup function can be achieved, thus achieving selectable input address length and selectable output result, ensuring the implementation of conventional and redundant operations. In the same electronic fuse memory, the capacity and the reliability can be balanced, thus not only avoiding the problem that the capacity is halved due to redundant backup, but also avoiding the reliability problem due to the lack of the redundant backup function, and reducing the chip area compared to the conventional dual-bit redundant backup application solution.

### BRIEF DESCRIPTION OF THE DRAWINGS

In order to more clearly describe the technical solutions in the present disclosure, the following will briefly introduce the drawings needed in the present disclosure. It is obvious that the drawings in the following description are only some embodiments of the present disclosure. Those skilled in the art may obtain other drawings from these drawings without contributing any inventive labor.

FIG. 1 is a schematic diagram of a working principle of dual-bit redundant backup of a conventional electronic fuse memory;

FIG. 2 is a modular structural diagram of an electronic fuse memory according to an embodiment of the present disclosure;

FIG. 3 is a schematic diagram of a signal flow of an electronic fuse memory in a normal working mode according to an embodiment of the present disclosure;

FIG. 4 is a schematic diagram of a signal flow of an electronic fuse memory in a dual-bit redundant mode according to an embodiment of the present disclosure;

FIG. 5 is a circuit diagram of an address switching module of an electronic fuse memory according to an embodiment of the present disclosure;

FIG. 6 is a diagram of a DBA and DBB signal forming circuit of an electronic fuse memory according to an embodiment of the present disclosure;

FIG. 7 is a circuit state diagram of k output mode selection modules of an electronic fuse memory in a dual-bit redundant working mode according to an embodiment of the present disclosure;

FIG. 8 is a circuit state diagram of k output mode selection modules of an electronic fuse memory in a normal working mode according to an embodiment of the present disclosure;

FIG. 9 is a diagram of a PSB and PSA signal forming circuit of an electronic fuse memory according to an embodiment of the present disclosure; and

FIG. 10 is a schematic diagram of input address and output word width of an electronic fuse memory according to an embodiment of the present disclosure.

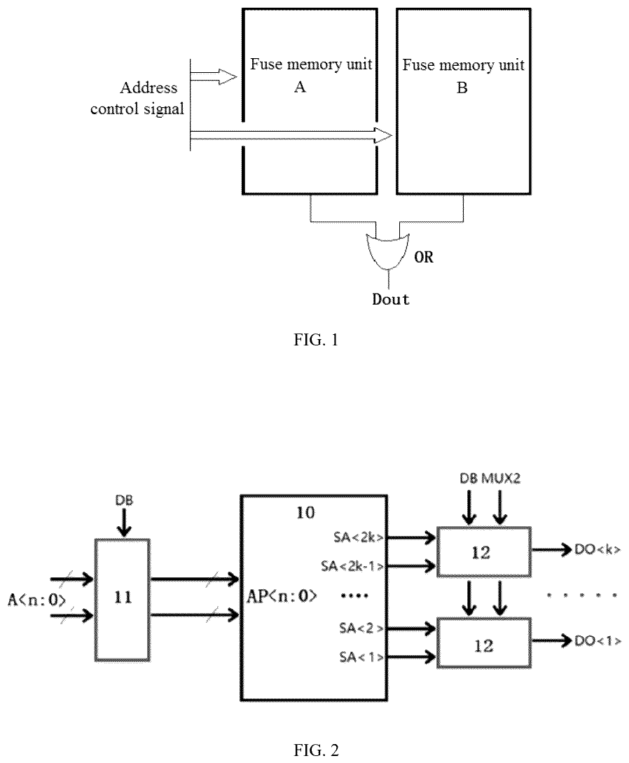

### DETAILED DESCRIPTION OF THE EMBODIMENTS

The technical solutions in the embodiments of the present disclosure will be clearly and completely described below with reference to the drawings in the embodiments of the present disclosure. Apparently, the described embodiments are merely some rather than all of the embodiments of the present disclosure. All other embodiments obtained by those skilled in the art based on the embodiments of the present disclosure without contributing any inventive labor shall still fall within the scope of protection of the present disclosure.

Words such as “first”, “second” and the like used in the present disclosure do not indicate any order, quantity, or importance, but are only intended to distinguish different components. Words such as “comprising” or “including” refer to a component or object that appears before the word, including those listed after the word and their equivalents, without excluding other components or objects. Words like “connecting” or “connected” are not limited to physical or mechanical connections, but may include electrical connections, whether direct or indirect. “Up”, “down”, “left”, “right”, and the like are only intended to represent relative positional relationships. When the absolute position of a described object changes, the relative positional relationship may also change correspondingly.

It is to be understood that, without conflict, the embodiments and features in the embodiments of the present disclosure may be freely combined with each other.

### Embodiment 1

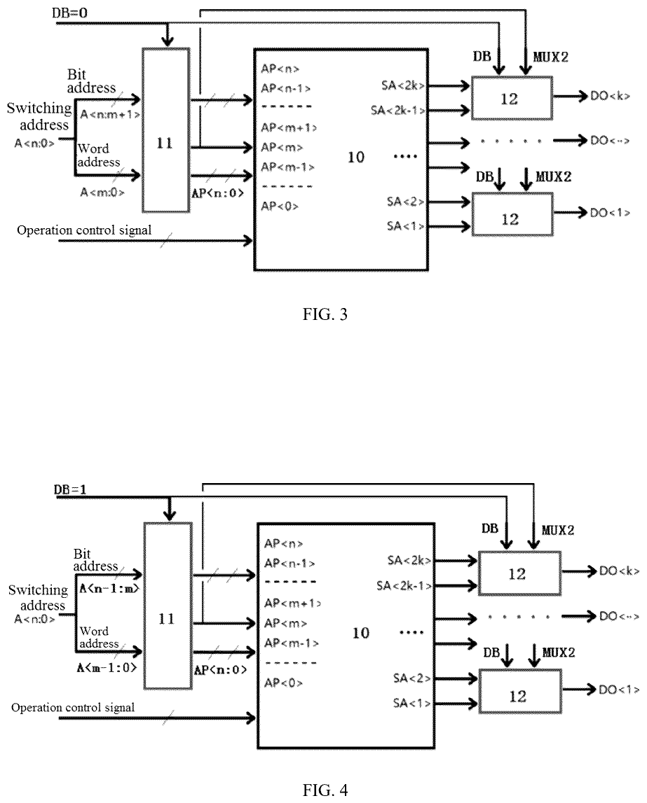

As shown in FIG. 2, an electronic fuse (efuse) memory includes a basic function module 10, an address switching module 11, and k output mode selection modules 12, where
the basic function module 10 has n+1 function address input ends AP<n:0> and 2 k fuse memory cell output ends; (m+1)th to nth function address input ends AP<n:m+1> are used as function bit address input ends, and 0th to mth function address input ends AP<m:0> are used as function word address input ends, where M is a positive integer, n is an integer greater than m, and k=2^{n-m};
the basic function module 10 includes k memory cell pairs, and each memory cell pair includes two fuse memory cells; outputs of two fuse memory cells of an ith memory cell pair are respectively SA<2i> and SA<2i−1>, where i is a positive integer less than or equal to k;
the address switching module 11 outputs n+1 bits of switching address input signals A<n:0> to the corresponding function address input ends of the basic function module 10 under the control of a dual-bit redundant mode enable signal DB;
the k output mode selection modules 12, under the control of the dual-bit redundant mode enable signal DB and a multiplexing selection signal MUX2, read out data stored in a normal working mode or data stored in a dual-bit redundant working mode of the basic function module 10;
control ends of all output mode selection modules 12 are respectively connected to the dual-bit redundant mode enable signal DB and the multiplexing selection signal MUX2;
two input ends of an ith output mode selection module 12 are respectively connected to the outputs SA<2i> and SA<2i−1> of the two fuse memory cells of the ith memory cell pair;
during a reading operation,
as shown in FIG. 3, in a case that the dual-bit redundant mode enable signal DB is 0, 0th-bit to nth-bit switching address input signals A<n:0> in total of n+1 bits are all valid, and the address switching module 11 is in the normal working mode, the 0th-bit to mth-bit switching address input signals A<m:0> are outputted as word addresses to m+1 function word line address input ends AP<m:0> of the basic function module 10, and the (m+1)th-bit to nth-bit switching address input signals A<n:m+1> are correspondingly outputted as bit addresses to n-m function bit line address input ends AP<n:m+1> of the basic function module 10;
as shown in FIG. 4, in a case that the dual-bit redundant mode enable signal DB is 1, the 0th-bit to (n−1)th-bit switching address input signals A<n−1:0> are valid, the nth-bit switching address input signal A<n> is invalid, the address switching module 11 is in the dual-bit redundant working mode, the 0th-bit to (m−1)th-bit switching address input signals A<m−1:0> are outputted as word addresses to m function word line address input ends AP<m−1:0> of the basic function module 10, the mth-bit to (n−1)th-bit switching address input signals A<n−1:m> are outputted as bit addresses to the other n−m function bit line address input ends AP<n:m+1> of the basic function module 10, and the mth-bit switching address input signal A<m> is simultaneously outputted as the multiplexing selection signal MUX2 to the k output mode selection modules 12;
in a case that the dual-bit redundant mode enable signal DB is 0, the k output mode selection modules 12 are in the normal working mode; in a case that the multiplexing selection signal MUX2 is 1, an output of the ith output mode selection module 12 is SA<2i>; in a case that the multiplexing selection signal MUX2 is 0, the output of the ith output mode selection module 12 is SA<2i−1>;
in a case that the dual-bit redundant mode enable signal DB is 1, the k output mode selection modules 12 are in the dual-bit redundant working mode, and the output of the ith output mode selection module 12 is to perform a logic OR operation on the outputs SA<2i−1> and SA<2i> of the two fuse memory cells of the ith memory cell pair.

The 0th-bit to mth-bit switching address input signals A<m:0> of the switching address input signals A<n:0> are cyclically changed in a manner of progressively increasing by 1 from all 0s to all 1s during the reading operation. In a first half of an addressing cycle of the reading operation, the mth-bit switching address input signal A<m> is 0. In a second half of the addressing cycle of the reading operation, the mth-bit switching address input signal A<m> is 1. Therefore, during the reading operation in the dual-bit redundant mode, the mth-bit switching address input signal A<m> can be used as the multiplexing selection signal MUX2 for one-out-of-two control to control the k output mode selection modules 12, so that the ith output mode selection module 12 outputs SA<2i> in the first half of the addressing cycle of the operation, and outputs SA<2i−1> in the second half of the addressing cycle of the operation to read out all data. For example, if an 8-bit number (D7 to D0) needs to be outputted, the highest bit of the 8-bit address is used for control selection. As we know, for an 8-bit number, its binary address is 3-bit (A2 to A0). Therefore, the high-bit address A2 is used as a control signal. In a case that A2=1, D7 to D4 of the 8 bits are outputted; in a case that A2=0, D3 to D0 are outputted. In this way, by multiplexing the selection signal MUX2, the reading of all data is achieved in two steps.

In the electronic fuse memory provided in embodiment 1, an address switching module 11 and output mode selection modules 12 are added on the basis of the conventional basic function module 10, a dual-bit redundant mode enable signal DB is added as an enable signal for the dual-bit redundant working mode on the basis of the original control signal and is used for controlling the state of the address switching module 11, and the settings of the dual-bit redundant mode enable signal DB and the switching address input signal are different in the normal working mode and the dual-bit redundant working mode; in a case that DB=0, addresses A<n:0> are valid, and the address switching module 11 is in the normal working mode; in a case that DB=1, addresses A<n−1:0> are valid, and the address switching module 11 is in the dual-bit redundant working mode; during the reading operation, the output mode selection module 12 have the function of switching between the normal output and the dual-bit redundant output; under the control of the dual-bit redundant mode enable signal DB and the multiplexing selection signal MUX2, the k output mode selection modules 12 not only can read the data stored in the normal working mode of the 2 k fuse memory cells of the basic function module 10, but also can read the data stored in the dual-bit redundant working mode of the k memory cell pairs of the basic function module 10; the output mode selection modules 12 not only can achieve the separate output of the data stored in each fuse memory cell, but also can perform a logic OR operation on the two fuse memory cells of the same memory cell pair before output.

The electronic fuse memory provided in embodiment 1 can provide two working modes, i.e., a normal working mode and a dual-bit redundant working mode, for customers to select. In the normal working mode, all storage space can be used, and in the dual-bit redundant working mode, a redundant backup function can be achieved, thus achieving selectable input address length and selectable output result, ensuring the implementation of conventional and redundant operation. In the same electronic fuse memory, the capacity and the reliability can be balanced, thus not only avoiding the problem that the capacity is halved due to redundant backup, but also avoiding the reliability problem due to the lack of the redundant backup function, and reducing the chip area compared to the conventional dual-bit redundant backup application solution.

### Embodiment 2

Based on the electronic fuse memory provided in embodiment 1, during a programming operation,
in a case that the dual-bit redundant mode enable signal DB is 0, the 0th-bit to nth-bit switching address input signals A<n:0> in total of n+1 bits are all valid, and the address switching module 11 is in the normal working mode and independently writes corresponding data respectively to the 2 k fuse memory cells of the basic function module 10;
in a case that the dual-bit redundant mode enable signal DB is 1, the 0th-bit to (n−1)th-bit switching address input signals A<n−1:0> are valid, the nth-bit switching address input signal A<n> is invalid, the address switching module 11 is in the dual-bit redundant working mode and writes data respectively to the k memory cell pairs of the basic function module 10, and the same data are written to the two fuse memory cells of the same one of the k memory cell pairs.

For the electronic fuse memory provided in embodiment 2, in a case that the dual-bit redundant mode enable signal DB is 0, the address switching module 11 performs normal addressing: AP<n>=A<n>, AP<n−1>=A<n−1>, . . . , AP<1>=A<1>, AP<0>=A<0>; in a case that the dual-bit redundant mode enable signal DB is 1, the address switching module 11 performs dual-bit addressing: AP<n>=A<n−1>, AP<n−1>=A<n−2>, . . . , AP<m+1>=A<m>, AP<m>=A<m>, . . . , AP<1>=A<1>, AP<0>=A<0>. The address switching module 11 not only can achieve independent access and programming of all addresses in the storage capacity of the basic function module 10, but also can achieve simultaneous access to two addresses and programming of these two addresses, thus achieving the function of switching between normal addressing and dual-bit addressing in the programming mode.

### Embodiment 3

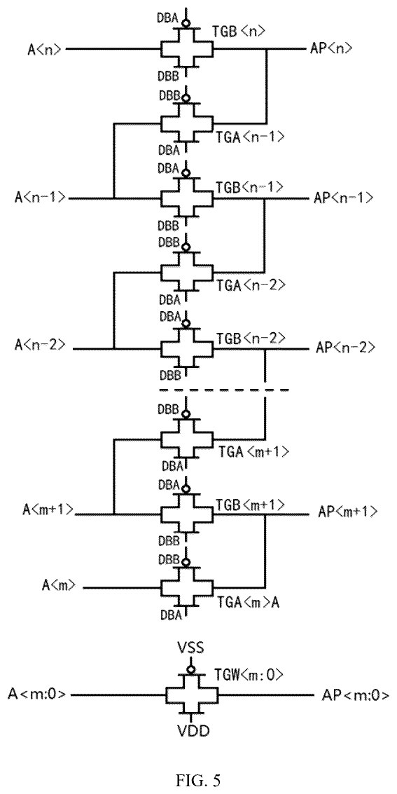

Based on the electronic fuse memory provided in embodiment 1, as shown in FIG. 5, the address switching module 11 includes main transmission gates TGB and auxiliary transmission gates TGA;
the mth-bit switching address input signal A<m> is connected to an input end of an mth auxiliary transmission gate TGA<m>;
an output end of the mth auxiliary transmission gate TGA<m> is connected to an (m+1)th function address input end AP<m+1> of the basic function module 10;
an input end of a jth auxiliary transmission gate TGA<j> is connected to a jth-bit switching address input signal A<j>, and an output end of the jth auxiliary transmission gate TGA<j> is connected to a (j+1)th function address input end AP<j+1> of the basic function module 10, where j is an integer greater than or equal to m and less than n;
an input end of a jth main transmission gate TGB<j> is connected to the jth-bit switching address input signal A<j>, and an output end of the jth main transmission gate TGB<j> is connected to a jth function address input end AP<j> of the basic function module 10;
an input end of an nth main transmission gate TGB<n> is connected to the nth-bit switching address input signal A<n>, and an output end of the nth main transmission gate TGB<n>is connected to an nth function address input end AP<n> of the basic function module 10;
the main transmission gates TGB are turned on in a case that DB is 0 and turned off in a case that DB is 1;
the auxiliary transmission gates TGA are turned on in a case that DB is 1 and turned off in a case that DB is 0.

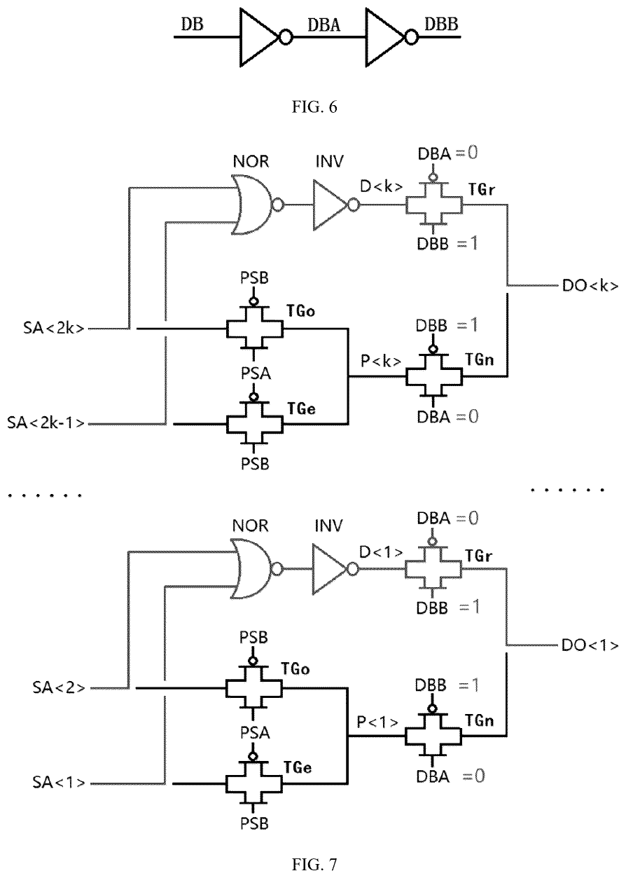

In some embodiments, each of the main transmission gates TGB and the auxiliary transmission gates TGA is composed of an NMOS transistor and a PMOS transistor;
a drain end of the NMOS transistor is short-circuited to a source end of the PMOS transistor as an input end of each transmission gate;
a source end of the NMOS transistor is short-circuited to a drain end of the PMOS transistor as an output end of each transmission gate;
a gate of the PMOS transistor of each main transmission gate TGB is connected to DBA, and a gate of the NMOS transistor is connected to DBB;
a gate of the PMOS transistor of each auxiliary transmission gate TGB is connected to DBB, and a gate of the NMOS transistor is connected to DBA;
As shown in FIG. 6, DBA and the dual-bit redundant mode enable signal DB are out of phase, and DBB and the dual-bit redundant mode enable signal DB are in phase;
a state of the dual-bit redundant mode enable signal DB at a high level is state 1, and a state at a low level is state 0.

In some embodiments, the address switching module 11 further includes word line transmission gates TGW;
the 0th-bit switching address input signal A<0> to the mth-bit switching address input signal A<m> are respectively connected to input ends of a 0th word line transmission gate TGW<0> to an mth word line transmission gate TGW<m>;
output ends of the 0th word line transmission gate TGW<0> to the mth word line transmission gate TGW<m> are respectively connected to the 0th to mth function address input ends AP<m:0> of the basic function module 10;
each word line transmission gate TGW<m:0> is turned on in a case that the electronic fuse memory is powered on.

In some embodiments, each word line transmission gate TGW<m:0> is composed of an NMOS transistor and a PMOS transistor;
a drain end of the NMOS transistor is short-circuited to a source end of the PMOS transistor as an input end of each word line transmission gate;
a source end of the NMOS transistor is short-circuited to a drain end of the PMOS transistor as an output end of each word line transmission gate;
a gate of the PMOS transistor of each word line transmission gate TGW is connected to a low working voltage VSS, and a gate of the NMOS transistor is connected to a high working voltage VDD.

For the electronic fuse memory provided in embodiment 3, the (m+1)th-bit switching address input signal A<m+1> to the nth-bit switching address input signal A<n> are respectively connected to the (m+1)th to nth function address input ends AP<n:m+1> of the basic function module 10 through first-stage controlled main transmission gates TGB<n:m+1>; the mth-bit switching address input signal A<m> to the nth-bit switching address input signal A<n−1> are respectively connected to the mth to (n−1)th function address input ends AP<n−1:m> of the basic function module 10 through first-stage controlled auxiliary transmission gates TGA<n−1:m>; the positive and negative control ends of all main transmission gates TGB and auxiliary transmission gates TGA are respectively connected to the out-of-phase signal DBA and the in-phase signal DBB of the dual-bit redundant mode enable signal DB. The 0th switching address input signal A<0> to the mth switching address input signal A<m> can be respectively connected to the 0th to mth function address input ends AP<m:0> of the basic function module 10 through first-stage normally-open word line transmission gates TGW<m:0>.

### Embodiment 4

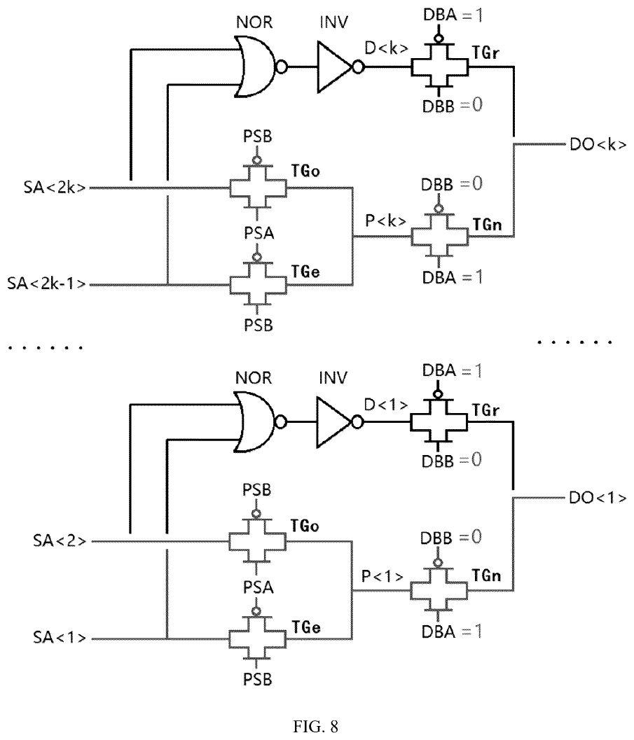

Based on the electronic fuse memory provided in embodiment 1, as shown in FIG. 7 and FIG. 8, each output mode selection module 12 includes an even transmission gate TGo, an odd transmission gate TGe, a normal transmission gate TGn, a redundant transmission gate TGr, a NOR gate, and a NOT gate INV;
two input ends of the NOR gate of the ith output mode selection module 12 are respectively connected to the outputs SA<2i> and SA<2i−1> of the two fuse memory cells of the ith memory cell pair of the basic function module 10; an output end of the NOR gate is connected to an input end of the NOT gate INV; an output end of the NOT gate INV is connected to an input end of the redundant transmission gate TGr; an output end of the redundant transmission gate TGr is connected to an ith selection output end DO<i>; an input end of the even transmission gate TGo is connected to the output SA<2i> of one fuse memory cell of the ith memory cell pair of the basic function module 10, and an output end is short-circuited to an input end of the normal transmission gate TGn; an input end of the odd transmission gate TGe is connected to the output SA<2i−1> of the other fuse memory cell of the ith memory cell pair of the basic function module 10, and an output end is short-circuited to the input end of the normal transmission gate TGn; an output end of the normal transmission gate TGn is connected to the ith selection output end DO<i>;
the normal transmission gate TGn is turned on in a case that DB is 0 and turned off in a case that DB is 1;
the redundant transmission gate TGr is turned on in a case that DB is 1 and turned off in a case that DB is 0;
the even transmission gate TGo is turned on in a case that the multiplexing selection signal MUX2 is 1 and turned off in a case that the multiplexing selection signal MUX2 is 0;
The odd transmission gate TGe is turned on in a case that the multiplexing selection signal MUX2 is 0 and turned off in a case that the multiplexing selection signal MUX2 is 1.

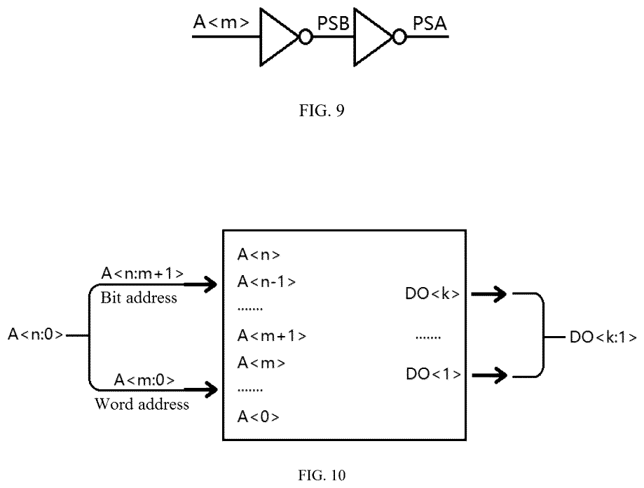

In some embodiments, each of the even transmission gate TGo, the odd transmission gate TGe, the normal transmission gate TGn, and the redundant transmission gate TGr is composed of an NMOS transistor and a PMOS transistor;
a drain end of the NMOS transistor is short-circuited to a source end of the PMOS transistor as an input end of each transmission gate;
a source end of the NMOS transistor is short-circuited to a drain end of the PMOS transistor as an output end of each transmission gate;
a gate of the PMOS transistor of the redundant transmission gate TGr is connected to DBA, and a gate of the NMOS transistor is connected to DBB;
a gate of the PMOS transistor of the normal transmission gate TGn is connected to DBB, and a gate of the NMOS transistor is connected to DBA;
a gate of the PMOS transistor of the even transmission gate TGo is connected to PSB, and a gate of the NMOS transistor is connected to PSA;
a gate of the PMOS transistor of the odd transmission gate TGe is connected to PSA, and a gate of the NMOS transistor is connected to PSB;
As shown in FIG. 7, DBA and the dual-bit redundant mode enable signal DB are out of phase, and DBB and the dual-bit redundant mode enable signal DB are in phase;
as shown in FIG. 9, PSB and the mth-bit switching address input signal A<m> are out of phase, and PSA and the mth-bit switching address input signal A<m> are in phase;
a state of the dual-bit redundant mode enable signal DB at a high level is state 1, and a state at a low level is state 0.

For the electronic fuse memory provided in embodiment 4, in a case that the dual-bit redundant mode enable signal DB is 1 and the dual-bit redundant working mode enters, as shown in FIG. 7, the two fuse memory cells of the ith memory cell pair of the basic function module 10 output SA<2i> and SA<2i−1> to enter an OR gate composed of the NOR gate and the NOT gate of the ith output mode selection module 12, which, after a logic OR operation, are outputted to the ith selection output end DO<i> of the ith output mode selection module 12 through the redundant transmission gate TGr in a turned-on state under the control of DB=1 signal. Although the two fuse memory cells of the ith memory cell pair of the basic function module 10 outputting SA<2i> and SA<2i−1> will also form a signal P<i> through the even transmission gate TGo and the odd transmission gate TGe, since the normal transmission gate TGn is turned off under the control of the dual-bit redundant mode enable signal (DB), it will not affect the state of the ith selection output end DO<i> of the ith output mode selection module 12.

In a case that the dual-bit redundant mode enable signal (DB) is 0 and the normal working mode enters, as shown in FIG. 8, contrary to the dual-bit redundant working mode described above, the two fuse memory cells of the ith memory cell pair of the basic function module 10 output SA<2i> and SA<2i−1> to enter an OR gate composed of the NOR gate and the NOT gate of the ith output mode selection module 12, which, after a logic OR operation, cannot reach the ith selection output end DO<i> of the ith output mode selection module 12 since the redundant transmission gate TGr is turned off under the control of DB=0 signal. The two fuse memory cells of the ith memory cell pair of the basic function module 10 outputting SA<2i> and SA<2i−1> will form a signal P<i> through the even transmission gate TGo and the odd transmission gate TGe, since the normal transmission gate TGn is turned on under the control of the dual-bit redundant mode enable signal (DB), the signal P<i> will be outputted to the ith selection output end DO<i> of the ith output mode selection module 12. It is particularly emphasized that at this time, the even transmission gate TGo and the odd transmission gate TGe form a one-out-of-two structure, with the mth-bit switching address input signal A<m> as the multiplexing selection signal (MUX2), which can be controlled through the highest bit A<m> of the word address in the switching address input signal. That is, in a case that A<m>=1, the high-bit SA<2i> is outputted; in a case that A<m>=0, the low-bit SA<2i−1> is outputted. In this way, the signals on all address bits can be outputted through the output ends Do<k> to D<0> of the k output mode selection modules 12.

It can be seen that for the electronic fuse memory provided in embodiment 4, in the normal working mode, the output of all data can be achieved by performing a one-out-of-two operation under the control of the highest bit A<m> of the word address in the switching address input signal; in the redundant working mode, the output of data after the logic OR operation can be achieved under the control of the dual-bit redundant mode enable signal DB.

For the electronic fuse memory provided in embodiment 4, since the dual-bit redundant working mode adopts two fuse memory cells to store one bit of data, the number of the addressing addresses of the basic function module 10 is half smaller than that in the normal working mode. In other words, if the dual-bit redundant working mode is selected, the number of bits of each input address required by the basic function module 10 is one bit smaller. A relationship between the bit addresses A<n:m+1> in the switching address input signals A<n:0> and the output ends DO<k:1> of the k output mode selection modules 12 is as shown in FIG. 10, where the bits of the word addresses in the switching address input signals A<n:0> are from 0 to m, so the word address length W=m+1; the bits of the bit addresses in the switching address input signals A<n:0> are from m+1 to n, so the bit address length B=n−m; since the output word length L of the k output mode selection modules 12 is equal to k, so the output word length L=2^{n-m}, thus obtaining that k=2^{n-m}. For example, for an electronic fuse memory with a capacity of 8192 bits, the switching address input signals are A<12:0>, the output word length is 32 bits, its bit addressing addresses are A<12:8>, and the word addressing addresses are A<7:0>. That is to say, the electronic fuse memory has a total of 256 words, the length of each word is 32 bits, and the total number of storage bits is 256*32=8192, thus obtaining that n=12, m=7, and k=32.

What are described above are only exemplary embodiments of the present disclosure, and are not intended to limit the present disclosure. Any modifications, equivalent replacements, improvements and the like made within the spirit and principle of the present disclosure shall all be included in the scope of protection of the present disclosure.

What is claimed is:

1. An electronic fuse memory, comprising a basic function module, an address switching module, and k output mode selection modules, wherein
the basic function module has n+1 function address input ends AP<n:0> and 2 k fuse memory cell output ends; (m+1)th to nth function address input ends AP<n:m+1> are used as function bit address input ends, and 0th to mth function address input ends AP<m:0> are used as function word address input ends, where M is a positive integer, n is an integer greater than m, and k=2^{n-m};
the basic function module comprises k memory cell pairs, and each memory cell pair comprises two fuse memory cells; outputs of two fuse memory cells of an ith memory cell pair are respectively SA<2i> and SA<2i−1>, where i is a positive integer less than or equal to k;
the address switching module outputs n+1 bits of switching address input signals A<n:0> to the corresponding function address input ends of the basic function module under the control of a dual-bit redundant mode enable signal DB;
the k output mode selection modules, under the control of the dual-bit redundant mode enable signal DB and a multiplexing selection signal MUX2, read out data stored in a normal working mode or data stored in a dual-bit redundant working mode of the basic function module;
control ends of all output mode selection modules are respectively connected to the dual-bit redundant mode enable signal DB and the multiplexing selection signal MUX2;
two input ends of an ith output mode selection module are respectively connected to the outputs SA<2i> and SA<2i−1> of the two fuse memory cells of the ith memory cell pair;
during a reading operation,
in a case that the dual-bit redundant mode enable signal DB is 0, 0th-bit to nth-bit switching address input signals A<n:0> in total of n+1 bits are all valid, and the address switching module is in the normal working mode, the 0th-bit to mth-bit switching address input signals A<m:0> are outputted as word addresses to m+1 function word line address input ends AP<m:0> of the basic function module, and the(m+1)th-bit to nth-bit switching address input signals A<n:m+1> are correspondingly outputted as bit addresses to n−m function bit line address input ends AP<n:m+1> of the basic function module;
in a case that the dual-bit redundant mode enable signal DB is 1, the 0th-bit to (n−1)th-bit switching address input signals A<n−1:0> are valid, the nth-bit switching address input signal A<n> is invalid, the address switching module is in the dual-bit redundant working mode, the 0th-bit to (m−1)th-bit switching address input signals A<m−1:0> are outputted as word addresses to m function word line address input ends AP<m−1:0> of the basic function module, the mth-bit to (n−1)th-bit switching address input signals A<n−1:m> are outputted as bit addresses to the other n−m function bit line address input ends AP<n:m+1> 0of the basic function module, and the mth-bit switching address input signal A<m> is simultaneously outputted as the multiplexing selection signal MUX2 to the k output mode selection modules;
in a case that the dual-bit redundant mode enable signal DB is 0, the k output mode selection modules are in the normal working mode; in a case that the multiplexing selection signal MUX2 is 1, an output of the ith output mode selection module is SA<2i>; in a case that the multiplexing selection signal MUX2 is 0, the output of the ith output mode selection module is SA<2i−1>;
in a case that the dual-bit redundant mode enable signal DB is 1, the k output mode selection modules are in the dual-bit redundant working mode, and the output of the ith output mode selection module is to perform a logic OR operation on the outputs SA<2i−1> and SA<2i> of the two fuse memory cells of the ith memory cell pair.

2. The electronic fuse memory according to claim 1, wherein
during a programming operation,
in a case that the dual-bit redundant mode enable signal DB is 0, the 0th-bit to nth-bit switching address input signals A<n:0> in total of n+1 bits are all valid, and the address switching module is in the normal working mode and independently writes corresponding data respectively to the 2 k fuse memory cells of the basic function module;
in a case that the dual-bit redundant mode enable signal DB is 1, the 0th-bit to (n−1)th-bit switching address input signals A<n−1:0> are valid, the nth-bit switching address input signal A<n> is invalid, the address switching module is in the dual-bit redundant working mode and writes data respectively to the k memory cell pairs of the basic function module, and the same data are written to the two fuse memory cells of the same one of the k memory cell pairs.

3. The electronic fuse memory according to claim 1, wherein
the address switching module comprises main transmission gates TGB and auxiliary transmission gates TGA;
the mth-bit switching address input signal A<m> is connected to an input end of an mth auxiliary transmission gate TGA<m>;
an output end of the mth auxiliary transmission gate TGA<m> is connected to an (m+1)th function address input end AP<m+1> of the basic function module;
an input end of a jth auxiliary transmission gate TGA<j> is connected to a jth-bit switching address input signal A<j>, and an output end of the jth auxiliary transmission gate TGA<j> is connected to a (j+1)th function address input end AP<j+1> of the basic function module, where j is an integer greater than or equal to m and less than n;
an input end of a jth main transmission gate TGB<j> is connected to the jth-bit switching address input signal A<j>, and an output end of the jth main transmission gate TGB<j> is connected to a jth function address input end AP<j> of the basic function module;
an input end of an nth main transmission gate TGB<n> is connected to the nth-bit switching address input signal A<n>, and an output end of the nth main transmission gate TGB<n> is connected to an nth function address input end AP<n> of the basic function module;
the main transmission gates TGB are turned on in a case that DB is 0 and turned off in a case that DB is 1;
the auxiliary transmission gates TGA are turned on in a case that DB is 1 and turned off in a case that DB is 0.

4. The electronic fuse memory according to claim 3, wherein
each of the main transmission gates TGB and the auxiliary transmission gates TGA is composed of an NMOS transistor and a PMOS transistor;
a drain end of the NMOS transistor is short-circuited to a source end of the PMOS transistor as an input end of each transmission gate;
a source end of the NMOS transistor is short-circuited to a drain end of the PMOS transistor as an output end of each transmission gate;
a gate of the PMOS transistor of each main transmission gate TGB is connected to DBA, and a gate of the NMOS transistor is connected to DBB;
a gate of the PMOS transistor of each auxiliary transmission gate TGB is connected to DBB, and a gate of the NMOS transistor is connected to DBA;
DBA and the dual-bit redundant mode enable signal DB are out of phase, and DBB and the dual-bit redundant mode enable signal DB are in phase;
a state of the dual-bit redundant mode enable signal DB at a high level is state 1, and a state at a low level is state 0.

5. The electronic fuse memory according to claim 3, wherein
the address switching module further comprises word line transmission gates TGW;
the 0th-bit switching address input signal A<0> to the mth-bit switching address input signal A<m> are respectively connected to input ends of a 0th word line transmission gate TGW<0> to an mth word line transmission gate TGW<m>;
output ends of the 0th word line transmission gate TGW<0> to the mth word line transmission gate TGW<m> are respectively connected to the 0th to mth function address input ends AP<m:0> of the basic function module;
each word line transmission gate TGW<m:0> is turned on in a case that the electronic fuse memory is powered on.

6. The electronic fuse memory according to claim 5, wherein
each word line transmission gate TGW<m:0> is composed of an NMOS transistor and a PMOS transistor;
a drain end of the NMOS transistor is short-circuited to a source end of the PMOS transistor as an input end of each word line transmission gate;
a source end of the NMOS transistor is short-circuited to a drain end of the PMOS transistor as an output end of each word line transmission gate;
a gate of the PMOS transistor of each word line transmission gate TGW is connected to a low working voltage VSS, and a gate of the NMOS transistor is connected to a high working voltage VDD.

7. The electronic fuse memory according to claim 1, wherein
each output mode selection module comprises an even transmission gate TGo, an odd transmission gate TGe, a normal transmission gate TGn, a redundant transmission gate TGr, a NOR gate, and a NOT gate INV;
two input ends of the NOR gate of the ith output mode selection module are respectively connected to the outputs SA<2i> and SA<2i−1> of the two fuse memory cells of the ith memory cell pair of the basic function module; an output end of the NOR gate is connected to an input end of the NOT gate INV; an output end of the NOT gate INV is connected to an input end of the redundant transmission gate TGr; an output end of the redundant transmission gate TGr is connected to an ith selection output end DO<i>; an input end of the even transmission gate TGo is connected to the output SA<2i> of one fuse memory cell of the ith memory cell pair of the basic function module, and an output end is short-circuited to an input end of the normal transmission gate TGn; an input end of the odd transmission gate TGe is connected to the output SA<2i−1> of the other fuse memory cell of the ith memory cell pair of the basic function module, and an output end is short-circuited to the input end of the normal transmission gate TGn; an output end of the normal transmission gate TGn is connected to the ith selection output end DO<i>;
the normal transmission gate TGn is turned on in a case that DB is 0 and turned off in a case that DB is 1;
the redundant transmission gate TGr is turned on in a case that DB is 1 and turned off in a case that DB is 0;
the even transmission gate TGo is turned on in a case that the multiplexing selection signal MUX2 is 1 and turned off in a case that the multiplexing selection signal MUX2 is 0;
The odd transmission gate TGe is turned on in a case that the multiplexing selection signal MUX2 is 0 and turned off in a case that the multiplexing selection signal MUX2 is 1.

8. The electronic fuse memory according to claim 1, wherein
each of the even transmission gate TGo, the odd transmission gate TGe, the normal transmission gate TGn, and the redundant transmission gate TGr is composed of an NMOS transistor and a PMOS transistor;
a drain end of the NMOS transistor is short-circuited to a source end of the PMOS transistor as an input end of each transmission gate;
a source end of the NMOS transistor is short-circuited to a drain end of the PMOS transistor as an output end of each transmission gate;
a gate of the PMOS transistor of the redundant transmission gate TGr is connected to DBA, and a gate of the NMOS transistor is connected to DBB;
a gate of the PMOS transistor of the normal transmission gate TGn is connected to DBB, and a gate of the NMOS transistor is connected to DBA;
a gate of the PMOS transistor of the even transmission gate TGo is connected to PSB, and a gate of the NMOS transistor is connected to PSA;
a gate of the PMOS transistor of the odd transmission gate TGe is connected to PSA, and a gate of the NMOS transistor is connected to PSB;
DBA and the dual-bit redundant mode enable signal DB are out of phase, and DBB and the dual-bit redundant mode enable signal DB are in phase;
PSB and the mth-bit switching address input signal A<m> are out of phase, and PSA and the mth-bit switching address input signal A<m> are in phase;
a state of the dual-bit redundant mode enable signal DB at a high level is state 1, and a state at a low level is state 0.

9. The electronic fuse memory according to claim 1, wherein
n=12, m=7, and k=32.
